(19) United States
(12) Patent Application Publication
(10) Pub. No.: US 2024/0168381 A1
(43) Pub. Date: May 23, 2024

(54) PHOTORESIST COMPOSITION FOR EXTREME ULTRAVIOLET, AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Jincheol PARK, Suwon-si (KR); Seonghyeon AHN, Suwon-si (KR); Honggu IM, Suwon-si (KR); Sungmin KO, Suwon-si (KR); Juyoung KIM, Suwon-si (KR); Juhyeon PARK, Suwon-si (KR); Naery YU, Suwon-si (KR)

(21) Appl. No.: 18/377,365

(22) Filed: Oct. 6, 2023

(30) Foreign Application Priority Data
Nov. 4, 2022 (KR) 10-2022-0146389

(51) Int. Cl. G03F 7/022; G03F 7/004; G03F 7/20

(52) U.S. Cl. CPC G03F 7/0226; G03F 7/0045; G03F 7/2004

(57) ABSTRACT

A photoresist composition for extreme ultraviolet (EUV) radiation and a method of manufacturing a semiconductor device, the photoresist composition includes a polymer resin; a photoacid generator; and a photoreactive additive that includes at least two diazonaphthoquinone (DNQ) groups, wherein the at least two DNQ groups are represented by Formula 1 or Formula 2 described herein.

### CROSS-REFERENCE TO RELATED APPLICATION

This application is based on and claims priority under 35 U.S.C. § 119 to Korean Patent Application No. 10-2022-0146389, filed on Nov. 4, 2022, in the Korean Intellectual Property Office, the disclosure of which is incorporated by reference herein in its entirety.

### BACKGROUND

### 1. Field

Embodiments relate to a photoresist composition for extreme ultraviolet (EUV) radiation and a method of manufacturing a semiconductor device using the photoresist composition for EUV.

### 2. Description of the Related Art

Along with the development of electronic technologies, down-scaling of semiconductor devices has rapidly progressed. Therefore, photolithography processes advantageous in forming fine patterns are used.

### SUMMARY

The embodiments may be realized by providing a photoresist composition for extreme ultraviolet (EUV) radiation, the photoresist composition including a polymer resin; a photoacid generator; and a photoreactive additive that includes at least two diazonaphthoquinone (DNQ) groups, wherein the at least two DNQ groups are represented by Formula 1 or Formula 2 below:

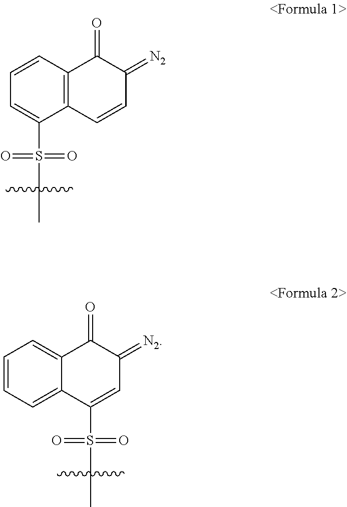

The embodiments may be realized by providing a photoresist composition for extreme ultraviolet (EUV) radiation, the photoresist composition including a photo-decomposable quencher; and a photoreactive additive that includes at least two diazonaphthoquinone (DNQ) groups, wherein the at least two DNQ groups are represented by Formula 1 or Formula 2 below:

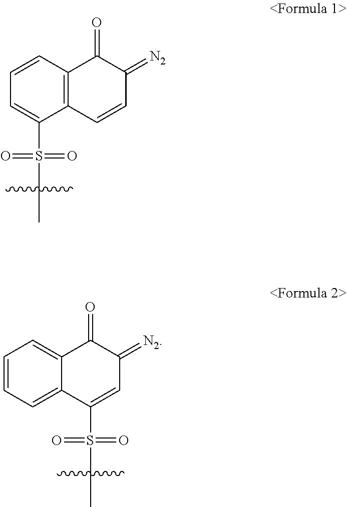

The embodiments may be realized by providing a method of manufacturing a semiconductor device, the method including forming a photoresist film by applying an extreme ultraviolet (EUV) photoresist composition on a film to be etched, the EUV photoresist composition including a polymer resin, a photoacid generator, a photo-decomposable quencher, and a photoreactive additive including at least two photo decomposable (DNQ) groups represented by Formula 1 or Formula 2 below; forming bonds between the at least two DNQ groups and the polymer resin in the photoresist film; exposing the photoresist film to EUV radiation; and forming a photoresist pattern by removing a partial region of the photoresist film,

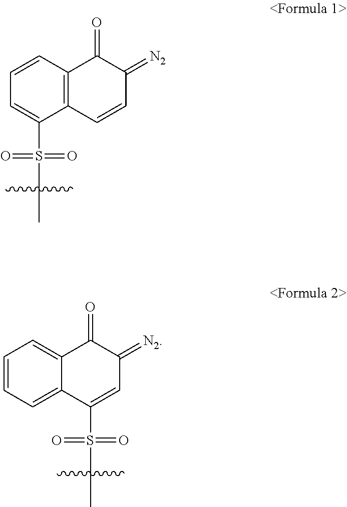

### BRIEF DESCRIPTION OF THE DRAWINGS

Features will become apparent to those of skill in the art by describing in detail exemplary embodiments with reference to the attached drawings in which:

FIGS. 1A and 1B are views illustrating an Example and a Comparative Example;

FIGS. 2A and 2B are plan views illustrating a photoresist pattern according to some embodiments; and

FIGS. 3 to 7 are views of stages in a method of manufacturing a semiconductor device according to some embodiments.

### DETAILED DESCRIPTION

In the present specification, the expression “substituted or unsubstituted” may mean substituted or unsubstituted with a hydrogen atom, a heavy hydrogen atom, a halogen atom, an alkyl group, a hydroxyl group, an alkoxy group, an ether group, an acetal group, a halogenated alkyl group, a halogenated alkoxy group, a halogenated ether group, an alkenyl group, a thio group, a sulfinyl group, a sulfonyl group, a carbonyl group, a phosphine oxide group, a phosphine sulfide group, an aryl group, a hydrocarbon ring group, or a heterocyclic group. In addition, each of the substituents listed above may be a substituted or unsubstituted substituent. For example, a halogenated alkyl group may be interpreted as an alkyl group. As used herein, the term “or” is not an exclusive term, e.g., “A or B” would include A, B, or A and B.

In the present specification, an alkyl group may refer to a linear alkyl group, a branched alkyl group, or a cyclic alkyl group. An alkyl group may include a primary alkyl, a secondary alkyl, and a tertiary alkyl. The number of carbon atoms of an alkyl group may vary. In an implementation, an alkyl group may have 1 to 7 carbon atoms, e.g., 1 to 5 carbon atoms.

In the present specification, when a chemical bond is not drawn at a position of a formula at which a chemical bond is to be drawn, there may be a hydrogen atom bonded to the position unless otherwise defined.

Hereinafter, embodiments will be described with reference to the accompanying drawings. In the drawings, like reference numerals refer to like elements, and overlapping descriptions thereof will be omitted.

A photoresist composition, and a method of manufacturing a semiconductor device using the photoresist composition will now be described according to embodiments.

In an implementation, the photoresist composition may be used for forming a pattern or manufacturing a semiconductor device. In an implementation, the photoresist composition may be used in a patterning process to manufacture a semiconductor device. The photoresist composition may be an extreme ultraviolet (EUV) photoresist composition. EUV rays may refer to ultraviolet rays having a wavelength of about 13.0 nm to about 13.9 nm, e.g., a wavelength of about 13.4 nm to about 13.6 nm. EUV rays may refer to light having energy of about 90 eV to about 95 eV. The photoresist composition may be of a chemically amplified resist type (CAR type).

In an implementation, the EUV photoresist composition may include a polymer resin, a photoacid generator, and a photoreactive additive including at least two diazonaphthoquinone (DNQ) groups.

In an implementation, the DNQ groups of the EUV photoresist composition may include a structure represented by Formula 1 below.

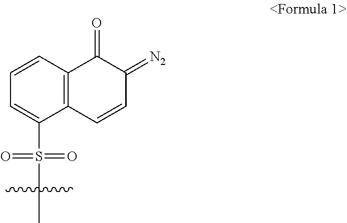

In an implementation, the DNQ groups of the EUV photoresist composition may have a structure represented by Formula 2 below:

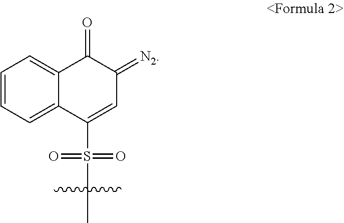

In Formulae 1 and 2, [symbol] is a bonding location.

In an implementation, in the photoresist composition, the photoreactive additive may include two or more DNQ groups. In an implementation, the photoreactive additive may be a compound having a structure including two or more DNQ groups as functional groups. In an implementation, the DNQ groups may be included in the photoreactive additive in a form bonded to oxygen (O), e.g., the bonding location of Formula 1 or Formula 2, above, may be bonded to an oxygen atom. In an implementation, the DNQ groups may be included in the photoreactive additive in a form directly or indirectly bonded to a benzene ring. In an implementation, the photoreactive additive may include a compound represented by one of Formulae 3A to 3E below.

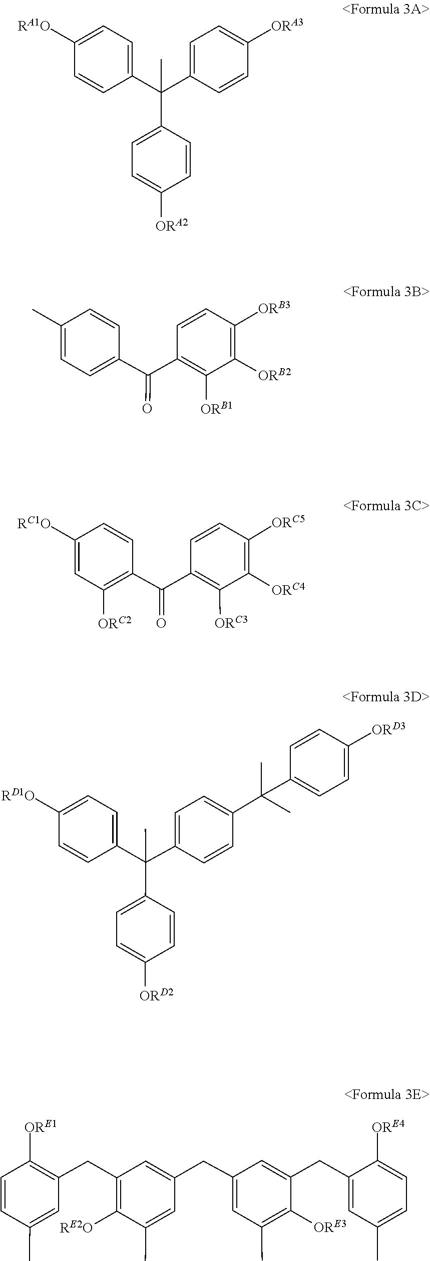

In Formulae 3A to 3E, R^{A1} to R^{A3}, R^{B1} to R^{B3}, R^{C1} to R^{C5}, R^{D1} to R^{D3}, and R^{E1} to R^{E4} may each independently be, e.g., a group represented by Formula 1 above, a group represented by Formula 2 above, or a hydrogen atom. In an implementation, at least two of R^{A1} to R^{A3} of Formula 3A, at least two of R^{B1} to R^{B3} of Formula 3B, at least two of R^{C1} to R^{C5} of Formula 3C, at least two of R^{D1} to R^{D3} of Formula 3D, and at least two of R^{E1} to R^{E4} of Formula 3E may be, e.g., a group represented by Formula 1 above or a group represented by Formula 2 above.

In an implementation, the photoreactive additive may be included in the photoresist composition in an amount of, e.g., greater than about 0 wt % to about 10 wt %, based on a weight of the polymer resin. In an implementation, the photoreactive additive represented by Formula 3E may be included in the photoresist composition in an amount of, e.g., greater than about 0 wt % to 10 wt %, based on the weight of the polymer resin.

In an implementation, a weight ratio of the photoreactive additive to the photoresist composition may be adjusted such that the total number of DNQ groups of the photoreactive additive may be greater than about 0% of to the total number of hydroxyl groups of the polymer resin but less than or equal to about 6% of the total number of hydroxyl groups of the polymer resin. In an implementation, when the photoreactive additive is represented by Formula 3E, the weight ratio of the photoreactive additive to the photoresist composition may be adjusted such that the total number of DNQ groups of the photoreactive additive may be greater than about 0% of the total number of hydroxyl groups of the polymer resin but less than or equal to about 6% of the total number of hydroxyl groups of the polymer resin.

The photoreactive additive may include a material that reacts to light. In an implementation, the photoreactive additive may include a material that reacts to EUV rays that are used for photoresist patterning. In an implementation, the photoreactive additive may include a material that reacts to secondary electrons emitted in the photoresist composition by EUV rays. In an implementation, two or more of the DNQ groups of the photoreactive additive may react to light. In an implementation, the DNQ groups may react to EUV rays used for photoresist patterning. In an implementation, the DNQ groups may react to secondary electrons emitted in the photoresist composition by EUV rays. A process in which the photoreactive additive and the DNQ groups react to EUV rays and secondary electrons emitted by the EUV rays will be described below.

In an implementation, the polymer resin of the EUV photoresist composition may include a compound in which a hydroxy styrene material monomer and a methacrylate monomer are polymerized. In an implementation, the polymer resin may include one or more hydroxyl groups. In an implementation, the polymer resin may be a compound in which one hydroxy styrene material monomer and two methacrylate monomers are copolymerized with each other. In an implementation, the polymer resin may be a compound obtained by copolymerization of one hydroxy styrene material monomer and two types of methacrylate monomers. In an implementation, the polymer resin may be a compound in which one hydroxy styrene material monomer and one methacrylate monomer are copolymerized. In an implementation, the hydroxy styrene material monomer may include a compound represented by Formula 4 below. In an implementation, the methacrylate monomer may include a compound represented by Formula 5 or Formula 6 below. The two types of methacrylate monomers may include compounds respectively represented by Formula 5 and Formula 6 below. In an implementation, the polymer resin may not include a novolac resin.

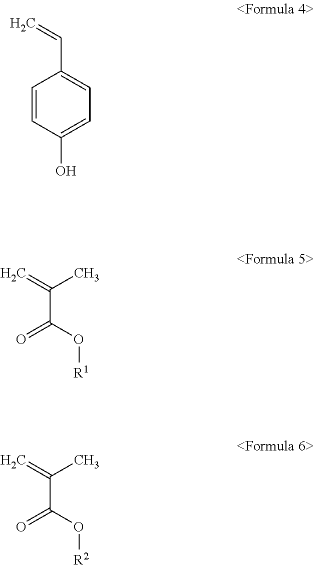

In Formulae 5 and 6, R¹ and R² may each independently be or include, e.g., hydrogen, a hydroxy group, a substituted or unsubstituted hydrocarbon group, a substituted or unsubstituted carbonyl group, a substituted or unsubstituted aldehyde group, a substituted or unsubstituted acyl group, a substituted or unsubstituted ester group, a substituted or unsubstituted substituted alkyl group, a substituted or unsubstituted alkenyl group, a substituted or unsubstituted alkanyl group, a substituted or unsubstituted phenyl group, a substituted or unsubstituted benzyl group, a substituted or unsubstituted aldehyde group, a substituted or unsubstituted ketone group, a substituted or unsubstituted carboxyl group, a substituted or unsubstituted amide group, a substituted or unsubstituted ether group, a substituted or unsubstituted acetal, a substituted or unsubstituted peroxy group, a substituted or unsubstituted amine group, a substituted or unsubstituted imine group, or a combinations thereof.

In an implementation, the polymer resin may interact with the photoreactive additive. In an implementation, the polymer resin containing one or more hydroxyl groups may interact with the photoreactive additive containing two or more DNQ groups. In an implementation, the hydroxyl groups of the polymer resin may form bonds by interacting with the DNQ groups of the photoreactive additive. In an implementation, the hydroxyl groups of the polymer resin may form hydrogen bonds by interacting with the DNQ groups of the photoreactive additive. In an implementation, two or more DNQ groups of the photoreactive additive may interact with respective hydroxy groups of two or more molecules of the polymer resin between the two or more molecules of the polymer resin and may thus form hydrogen bonds that connect the two or more molecules of the polymer resin to each other.

In an implementation, two or more DNQ groups of the photoreactive additive may interact with some hydroxyl groups of the polymer resin. In an implementation, other hydroxy groups of the polymer resin may not interact with the two or more DNQ groups of the photoreactive additive.

In an implementation, the EUV photoresist composition may form a photoresist pattern having an improved density, e.g., owing to the interaction between the DNQ groups of the photoreactive additive and the hydroxyl groups of the polymer resin. In an implementation, a photoresist pattern having a high aspect ratio may be formed using the EUV photoresist composition which includes the photoreactive additive having one or more DNQ groups. In an implementation, a pattern having a line width of about 40 nm or less may be formed using the EUV photoresist composition which includes the photoreactive additive having one or more DNQ groups.

In an implementation, as described above, the photoreactive additive and the DNQ groups may react to EUV rays and secondary electrons emitted by the EUV rays. In an implementation, the interaction between the photoreactive additive and the polymer resin may be removed by EUV rays and secondary electrons emitted by the EUV rays. In an implementation, bonds formed by the interaction between the DNQ groups of the photoreactive additive and the hydroxyl groups of the polymer resin may be broken by EUV rays and secondary electrons emitted by the EUV rays. In an implementation, bonds formed by the interaction between the DNQ groups of the photoreactive additive and the hydroxyl groups of the polymer resin may be removed by EUV rays and secondary electrons emitted by the EUV rays.

In an implementation, the EUV photoresist composition may form a photoresist film having high solubility in a portion exposed to EUV rays.

In an implementation, in the EUV photoresist composition, the photoreactive additive including one or more DNQ groups may be represented by Formula 3E above, and results of an experiment performed for this case are shown in Table 1 below. Table 1 shows resultant values of line width roughness (LWR) and line edge roughness (LER) obtained according to the amount of the photoreactive additive of the EUV photoresist composition when the photoreactive additive of the EUV photoresist composition is represented by Formula 3E above.

TABLE 1

| Weight ratio (wt %) of photoreactive | LER | LWR |
|---|---|---|
| additive to polymer resin | (nm) | (nm) |
| 0 | 2.29 | 3.2 |
| 2.5 | 2.07 | 2.89 |
| 6 | 2.12 | 2.95 |
| 7.5 | 2.1 | 2.91 |

Referring to Table 1, LER and LWR decreased when the photoreactive additive was included (2.5 wt %, 6 wt %, and 7.5 wt %) compared to when the photoreactive additive was not included (0 wt %). LER and LWR were further improved when the photoreactive additive was included in an amount of about 2.5 wt % based on the weight of the polymer resin and when the photoreactive additive was included in an amount of about 7.5 wt % based on the weight of the polymer resin.

In an implementation, LER and LWR may be improved by the EUV photoresist composition that includes the photoreactive additive having one or more DNQ groups.

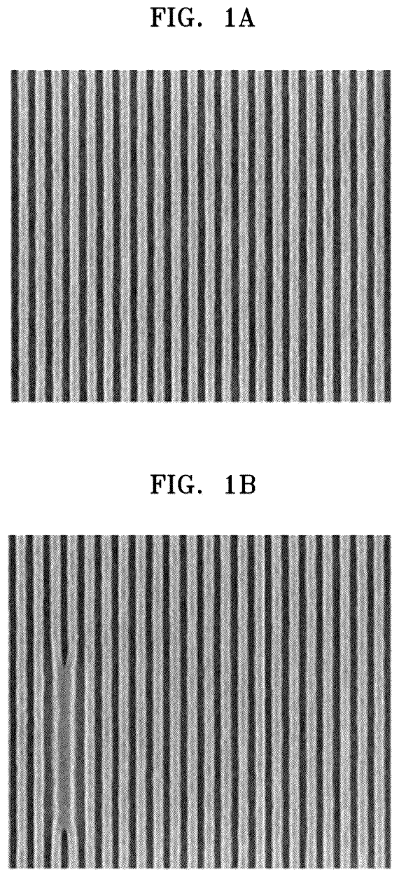

FIGS. 1A and 1B are diagrams illustrating an Example and a Comparative Example. FIG. 1A is an electron micrograph illustrating an experimental Example in which the EUV photoresist composition including the photoreactive additive having at least two DNQ groups is used according to an embodiment. FIG. 1B is an electron micrograph illustrating a Comparative Example in which an EUV photoresist composition that does not include a photoreactive additive having at least two DNQ groups is used for comparison with the example shown in FIG. 1A.

Referring to FIGS. 1A and 1B, patterns of the Example and patterns of the Comparative Example have the same size. The patterns of the Example shown in FIG. 1A do not have a collapsed portion, but the patterns of the Comparative Example shown in FIG. 1B have a collapsed portion. When fine and closely-arranged patterns having a high aspect ratio are formed, some of the fine and closely-arranged patterns could collapse due to the capillary phenomenon. However, when the photoreactive additive having at least two DNQ groups is included in the EUV photoresist composition, the EUV photoresist composition may be used to form a photoresist film having an improved density owing to the interaction between the DNQ groups of the photoreactive additive and the hydroxyl groups of the polymer resin as described above. The EUV photoresist composition, which may be used to form a photoresist film having an improved density, may help prevent a phenomenon in which small and narrow patterns collapse due to a capillary action in a high-aspect-ratio patterning process.

In an implementation, the photoacid generator of the EUV photoresist composition may generate an acid when exposed to light. In an implementation, the photoacid generator may generate an acid when exposed to EUV rays.

The photoacid generator may include, e.g., a triarylsulfonium salt, a diaryliodonium salt, sulfonate, or a mixture thereof. In an implementation, the photoacid generator may include, e.g., triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonate), N-hydroxysuccinimide triflate, norbornene-dicarboximide-triflate, triphenylsulfonium nonaflate, diphenyliodonium nonaflate, methoxydiphenyliodonium nonaflate, di-t-butyl diphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In an implementation, in the EUV photoresist composition, the photoacid generator may be included in an amount of about 0.1 wt % to about 5 wt % based on the total weight of the polymer resin.

In an implementation, the EUV photoresist composition may further include a photo-decomposable quencher.

In an implementation, when an acid generated by the photoacid generator of the EUV photoresist composition diffuses to an unexposed region of a photoresist film, a compound included in the photo-decomposable quencher may trap the acid in the unexposed region of the photoresist film. In an implementation, owing to the photo-decomposable quencher included in the EUV photoresist composition, the diffusion of an acid may be suppressed.

The photo-decomposable quencher may include a primary aliphatic amine, a secondary aliphatic amine, a tertiary aliphatic amine, an aromatic amine, an amine having a heterocyclic ring, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, an amide, an imide, a carbamate, or an ammonium salt. In an implementation, the photo-decomposable quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyl toluidine, or a combination thereof.

In an implementation, the photo-decomposable quencher may include a photo-decomposable base. The photo-decomposable base may include a compound capable of generating an acid when exposed to light and neutralizing an acid before being exposed to light. When the photo-decomposable base is decomposed by exposure to light, the photo-decomposable base may lose an acid-trapping function. Therefore, when light is incident on a region of a photoresist film formed of the EUV photoresist composition including the photo-decomposable quencher having the photo-decomposable base, the photo-decomposable base loses alkalinity in the exposed region of the photoresist film, and the photo-decomposable base traps an acid in an unexposed region of the photoresist film, thereby suppressing the diffusion of the acid from the exposed region to the unexposed region.

The photo-decomposable base may include a carboxylate or sulfonate salt of a photo-decomposable cation. In an implementation, the photo-decomposable cation may form a complex with an anion of a C1-C20 carboxylic acid. The carboxylic acid may be, e.g., formic acid, acetic acid, propionic acid, tartaric acid, succinic acid, cyclohexyl carboxylic acid, benzoic acid, or salicylic acid.

In an implementation, in the EUV photoresist composition, the photo-decomposable quencher may be included in an amount of, e.g., about 0.01 wt % to about 5.0 wt % based on the total weight of the polymer resin.

In an implementation, the EUV photoresist composition may further include an organic solvent. In an implementation, the organic solvent may include, e.g., an ether, an alcohol, a glycol ether, an aromatic hydrocarbon compound, a ketone, or an ester. In an implementation, the organic solvent may include, e.g., ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol mono Methyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, 2-hydroxyethylpropionate, 2-hydroxy-2-methylethylpropionate, ethoxyethyl acetate, hydroxyethyl acetate, 2-hydroxy-3-methylbutanoate, 3-methoxymethylpropionate, 3-methoxyethylpropionate, 3-ethoxyethylpropionate, 3-ethoxymethylpropionate, methyl pyruvate, ethyl pyruvate, ethyl acetate, butyl acetate, ethyl lactate, butyl lactate, or the like. Any one or a combination of the listed materials may be used as the organic solvent. In an implementation, the amount of the organic solvent in the EUV photoresist composition may be adjusted such that the EUV photoresist composition may have a solid content of about 3 wt % to about 20 wt %.

In an implementation, the EUV photoresist composition may further include a surfactant.

The surfactant may include, e.g., fluoroalkylbenzenesulfonate, fluoroalkylcarboxylate, fluoroalkylpolyoxyethylene ether, fluoroalkylammonium iodide, fluoroalkylbetaine, fluoroalkylsulfonate, diglycerin tetrakis (fluoroalkylpolyoxyethylene ether), fluoroalkyltrimethylammonium salt, fluoroalkylbenzenesulfonate, polyoxyethylene nonylphenyl ether, polyoxyethylene octylphenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan Laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonate, or alkyl diphenyl ether disulfonate. The surfactant may be included in an amount of, e.g., about 0.001 wt % to about 0.1 wt % based on the total weight of the polymer resin.

In an implementation, the EUV photoresist composition may further include a pigment, a preservative, an adhesion promoter, a coating aid, a plasticizer, a surface modifying agent, or a dissolution inhibitor.

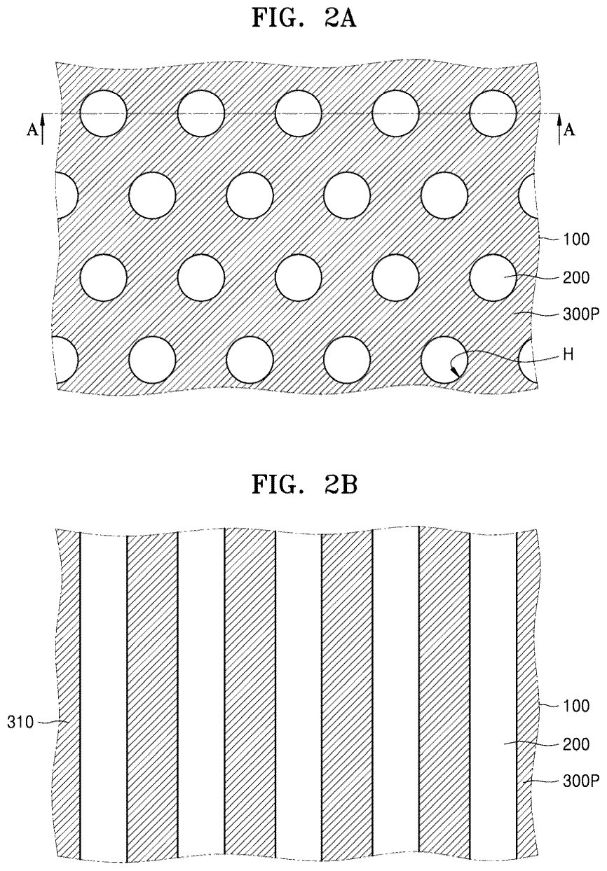

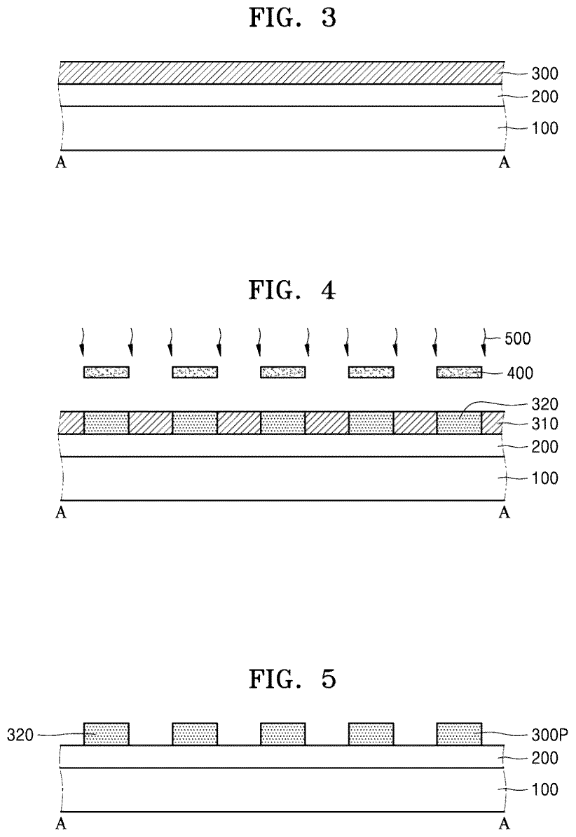

FIGS. 2A and 2B are plan views illustrating a photoresist pattern according to some embodiments. FIGS. 3 to 7 are views of stages in a method of manufacturing a semiconductor device according to some embodiments. For example, FIGS. 3 to 7 may be cross-sectional views taken along line A-A of FIG. 2A.

Referring to FIGS. 2A and 3, a substrate 100 may be provided. A lower film 200 and a photoresist film 300 may be sequentially formed on the substrate 100. The lower film 200 may be, e.g., a film to be etched. The lower film 200 may include, e.g., a semiconductor material, a conductive material, an insulating material, or a combination thereof. The lower film 200 may be a single layer or may include a plurality of stacked layers. In an implementation, the substrate 100 and the lower film 200 may not be in contact with each other. Other layers may be further disposed between the substrate 100 and the lower film 200.

The EUV photoresist composition of the embodiments may be applied to or on the lower film 200. A photoresist film 300 may be formed by the application of the EUV photoresist composition. The application of the EUV photoresist composition may be performed by a spin coating method. A heat treatment process may be further performed on the applied EUV photoresist composition. The heat treatment process may be a process of baking the photoresist film 300.

In an implementation, during a spin coating process of the EUV photoresist composition, the polymer resin may interact with the photoreactive additive. In an implementation, during the spin coating process of the EUV photoresist composition, the hydroxy groups of the polymer resin may interact with the DNQ groups of the photoreactive additive to form bonds.

Referring to FIGS. 2A and 4, the photoresist film 300 may be exposed to light 500. The light 500 may be electron beams or EUV rays. Before the light 500 is irradiated, a photo mask 400 may be disposed on the photoresist film 300. The light 500 may be irradiated to a first region 310 of the photoresist film 300 that is exposed through the photo mask 400.

When the photoresist film 300 is exposed to the light 500, the EUV photoresist composition may absorb light photons and may emit secondary electrons and hydrogen ions (H⁺) as described above. The EUV photoresist composition may react to the secondary electrons or the hydrogen ions (H⁺).

In an implementation, in the first region 310 of the photoresist film 300, the photoreactive additive and the DNQ groups may react to EUV rays and secondary electrons emitted by the EUV rays. In an implementation, the interaction between the photoreactive additive and the polymer resin in the first region 310 of the photoresist film 300 may be removed, disrupted, or otherwise broken by the EUV rays and the secondary electrons emitted by the EUV rays. In an implementation, the bonds formed in the first region 310 of the photoresist film 300 by the interaction between the DNQ groups of the photoreactive additive and the hydroxyl groups of the polymer resin may be broken by the EUV rays and the secondary electrons emitted by the EUV rays. In an implementation, the bonds formed in the first region 310 of the photoresist film 300 by the interaction between the DNQ groups of the photoreactive additive and the hydroxyl groups of the polymer resin may disappear by or in response to the EUV rays and the secondary electrons emitted by the EUV rays.

A second region 320 of the photoresist film 300 may not be exposed to the light 500. The chemical structure of the photoresist composition in the second region 320 of the photoresist film 300 may not change.

In an implementation, the interaction between the photoreactive additive and the polymer resin may be maintained in the photoresist film 300 of the second region 320. In an implementation, bonds formed by the interaction between the DNQ groups of the photoreactive additive and the hydroxyl groups of the polymer resin may be maintained in the second region 320 of the photoresist film 300.

In an implementation, after the photoresist film 300 is exposed to the light 500, the material of the photoresist film 300 may have different chemical structures in the first and second regions 310 and 320. In an implementation, bonds formed by the interaction between the DNQ groups of the photoreactive additive and the hydroxyl groups of the polymer resin may be broken in the first region 310 of the photoresist film 300 and may be maintained in the second region 320 of the photoresist film 300. Some secondary electrons or hydrogen ions (H⁺) generated in the first region 310 of the photoresist film 300 could move to the second region 320 of the photoresist film 300, and in this case, the structure of the second region 320 of the photoresist film 300 could be changed.

In an implementation, the photo-decomposable quencher may help prevent secondary electrons or hydrogen ions generated in the first region 310 from moving to the second region 320. In an implementation, the first region 310 and the second region 320 of the photoresist film 300 may be accurately formed at desired positions. Thereafter, the photo mask 400 may be removed.

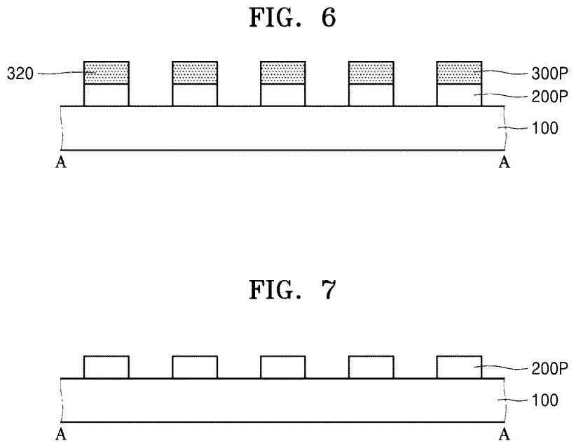

Referring to FIGS. 2A and 5, a photoresist pattern 300P may be formed by removing the first region 310 from the photoresist film 300 using a developing solution. The first region 310 of the photoresist film 300 may be reactive with (e.g., soluble in) the developing solution. The second region 320 of the photoresist film 300 may not be reactive with (e.g., soluble in) the developer. In an implementation, the first region 310 of the photoresist film 300 may be selectively removed. The photoresist pattern 300P may correspond to the second region 320 of the photoresist film 300. The photoresist pattern 300P may expose the lower film 200. EUV rays have high energy per photon. In an implementation, the photoresist pattern 300P may have a fine width and pitch. The photoresist pattern 300P may have reduced LER and LWR.

The photoresist pattern 300P may be formed through a patterning process in which an exposure process and a development process are performed on the photoresist film 300.

In an implementation, the interaction between the photoreactive additive and the polymer resin in the first region 310 of the photoresist film 300 may be removed by EUV rays and secondary electrons generated in the photoresist film 300 by the EUV rays, and R¹ in Formula 5 or R² in Formula 6 may be deprotected by hydrogen ions (H⁺) emitted by the EUV rays and may thus be reactive with the developing solution. In an implementation, bonds formed by the interaction between the DNQ groups of the photoreactive additive and the hydroxyl groups of the polymer resin in the first region 310 of the photoresist film 300 may be broken by EUV rays and secondary electrons generated in the photoresist film 300 by the EUV rays, and R¹ in Formula 5 or R² in Formula 6 may be deprotected by hydrogen ions (H⁺) emitted by the EUV rays may thus be reactive with the developing solution. In an implementation, bonds formed by the interaction between the DNQ groups of the photoreactive additive and the hydroxyl groups of the polymer resin in the first region 310 of the photoresist film 300 may disappear by or in response to EUV rays and secondary electrons or hydrogen ions (H⁺) emitted by the EUV rays, and thus the first region 310 may be reactive with or soluble in the developing solution.

In an implementation, the interaction between the photoreactive additive and the polymer resin may be maintained in the second region 320 of the photoresist film 300, and thus the second region 320 may not be reactive with or soluble in the developing solution. In an implementation, bonds formed in the second region 320 of the photoresist film 300 by the interaction between the DNQ groups of the photoreactive additive and the hydroxyl groups of the polymer resin may be maintained, and thus the second region 320 may not be reactive with the developing solution.

In an implementation, the first region 310 of the photoresist film 300 may be selectively removed, and the second region 320 of the photoresist film 300 may not be removed, thereby forming the photoresist pattern 300P. In an implementation, in the photoresist pattern 300P formed of the EUV photoresist composition, the DNQ groups of the photoreactive additive may interact with the hydroxyl groups of the polymer resin and form bonds. In an implementation, the DNQ groups of the photoreactive additive may interact with the hydroxyl groups of the polymer resin and may thus form bonds.

As shown in FIG. 2A, the photoresist pattern 300P may have a plurality of holes H. Each of the holes H may have a circular shape. The holes H of the photoresist pattern 300P may be arranged in a honeycomb form. In an implementation, the holes H of the photoresist pattern 300P may have various shapes such as a zigzag shape, a polygonal shape, or a circular shape.

As shown in FIG. 2B, the photoresist pattern 300P may have a linear planar shape. In an implementation, the photoresist pattern 300P may include portions extending in one direction. The planar shape of the photoresist pattern 300P may be variously modified.

Referring to FIGS. 2A and 6, portions of the lower film 200 exposed through the photoresist pattern 300P may be removed to form a lower pattern 200P. Removal of the lower film 200 may be performed through an etching process. The lower film 200 may have etch selectivity with respect to the photoresist pattern 300P. The lower pattern 200P may expose the substrate 100. In an implementation, the lower pattern 200P may expose another layer between the substrate 100 and the lower pattern 200P. The lower pattern 200P may have a width corresponding to a width of the photoresist pattern 300P. In an implementation, the photoresist pattern 300P may have a small width, and the lower pattern 200P may have a small width. In an implementation, the photoresist pattern 300P may have improved LER and LWR, and the lower pattern 200P may have improved width uniformity. In an implementation, the photoresist pattern 300P may be accurately formed at a desired position, and the accuracy of patterning of the lower pattern 200P may be improved.

Referring to FIGS. 2A and 7, the photoresist pattern 300P may be removed. Then, pattern formation may be finished. In an implementation, the lower pattern 200P may be an element of a semiconductor device. In an implementation, the lower pattern 200P may be a semiconductor pattern, a conductive pattern, or an insulating pattern of a semiconductor device.

By way of summation and review, in photolithography processes for manufacturing integrated circuit devices, improving the efficiency of a development process as well as improving the contrast between the solubility of an exposed region of a photoresist film and an unexposed region of the photoresist film may be considered.

One or more embodiments may provide an extreme ultraviolet (EUV) photoresist composition for forming a photoresist film having improved density.

One or more embodiments may provide an EUV photoresist composition for forming a pattern having a high aspect ratio.

One or more embodiments may provide an EUV photoresist composition for forming a photoresist pattern having improved line width roughness (LWR) and line edge roughness (LER).

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoresist composition for extreme ultraviolet (EUV) radiation, the photoresist composition comprising:
a polymer resin;
a photoacid generator; and
a photoreactive additive that includes at least two diazonaphthoquinone (DNQ) groups,
wherein the at least two DNQ groups are represented by Formula 1 or Formula 2 below:

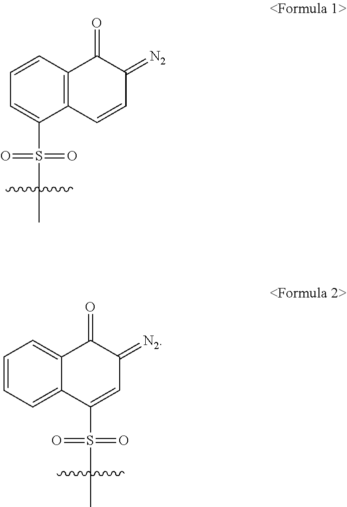

2. The photoresist composition for EUV radiation as claimed in claim 1, wherein all of the at least two DNQ groups are bonded to the polymer resin.

3. The photoresist composition for EUV radiation as claimed in claim 2, wherein:
the polymer resin includes at least one hydroxyl group, and
the at least two DNQ groups are bonded to the at least one hydroxyl group of the polymer resin.

4. The photoresist composition for EUV radiation as claimed in claim 1, wherein:
the photoreactive additive includes a compound represented by one of Formulae 3A to 3E below: 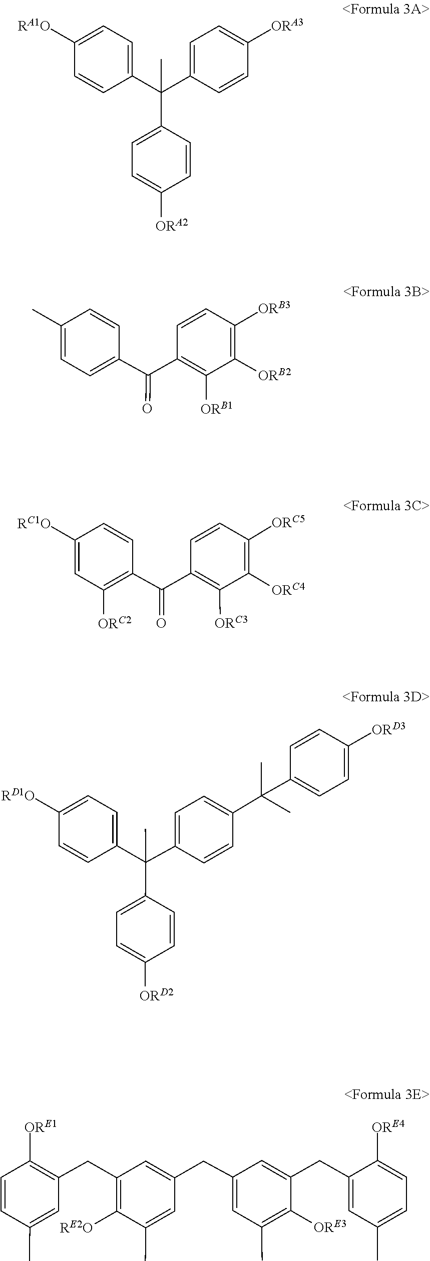
in Formulae 3A to 3E,
R^{A1} to R^{A3}, R^{B1} to R^{B3}, R^{C1}to R^{C5}, R^{D1} to R^{D3}, and R^{E1} to R^{E4} are each independently a group represented by Formula 1, a group represented by Formula 2, or a hydrogen atom, and
at least two of R^{A1} to R^{A3} of Formula 3A, at least two of R^{B1} to R^{B3} of Formula 3B, at least two of R^{C1}to R^{C5} of Formula 3C, at least two of R^{D1} to R^{D3} of Formula 3D, and at least two of R^{E1} to R^{E4} of Formula 3E are a group represented by Formula 1 or a group represented by Formula 2.

5. The photoresist composition for EUV radiation as claimed in claim 1, wherein:
the polymer resin includes at least one hydroxyl group, and
a total number of DNQ groups in the photoreactive additive is greater than about 0% of a total number of hydroxyl groups in the polymer resin and is less than or equal to about 6% of the total number of hydroxyl groups in the polymer resin.

6. The photoresist composition for EUV radiation as claimed in claim 1, further comprising a photo-decomposable quencher.

7. The photoresist composition for EUV radiation as claimed in claim 1, wherein the polymer resin does not include a novolac resin.

8. The photoresist composition for EUV radiation as claimed in claim 1, wherein the polymer resin includes a resin in which a hydroxy styrene material monomer and a methacrylate monomer are polymerized.

9. A photoresist composition for extreme ultraviolet (EUV) radiation, the photoresist composition comprising:
a photo-decomposable quencher; and
a photoreactive additive that includes at least two diazonaphthoquinone (DNQ) groups,
wherein the at least two DNQ groups are represented by Formula 1 or Formula 2 below:

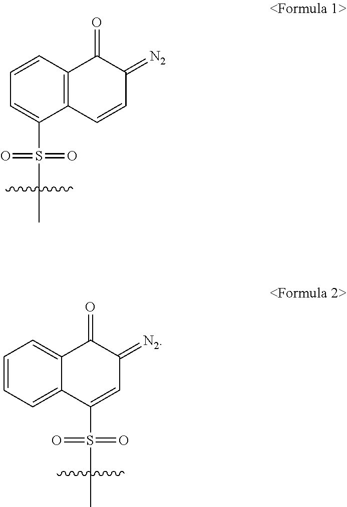

10. The photoresist composition for EUV radiation as claimed in claim 9, further comprising a polymer resin that includes at least one hydroxyl group,
wherein the at least two DNQ groups are bonded to the at least one hydroxyl group of the polymer resin.

11. The photoresist composition for EUV radiation as claimed in claim 10, wherein the polymer resin includes a resin in which a hydroxy styrene material monomer and a methacrylate monomer are polymerized.

12. The photoresist composition for EUV radiation as claimed in claim 9, wherein each of the at least two DNQ groups is bonded to an oxygen (O) included in the photoreactive additive.

13. The photoresist composition for EUV radiation as claimed in claim 9, wherein:
the photoreactive additive includes a compound represented by one of Formulae 3A to 3E below: 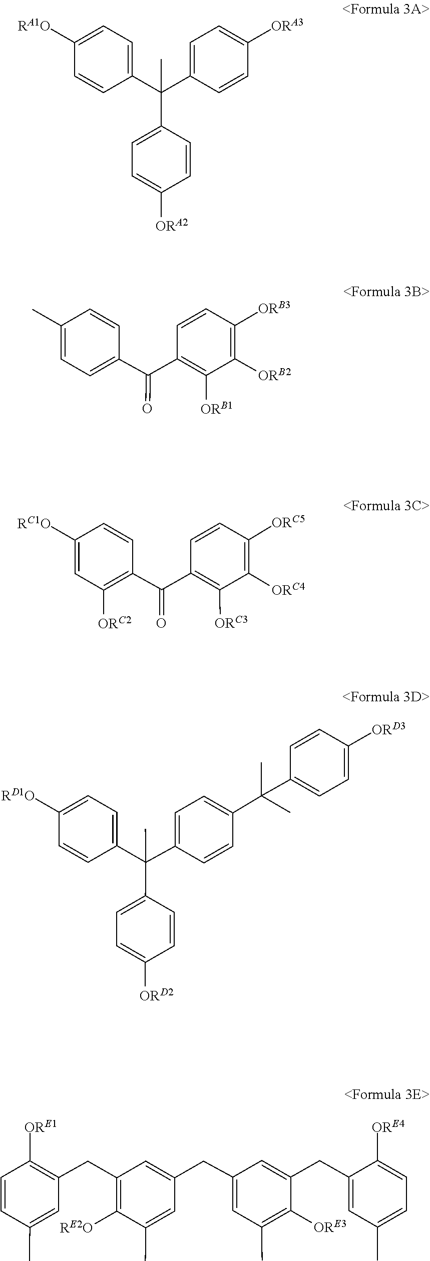
in Formulae 3A to 3E,
R^{A1} to R^{A3}, R^{B1} to R^{B3}, R^{C1}to R^{C5}, R^{D1} to R^{D3}, and R^{E1} to R^{E4} are each independently a group represented by Formula 1, a group represented by Formula 2, or a hydrogen atom, and
at least two of R^{A1} to R^{A3} of Formula 3A, at least two of R^{B1} to R^{B3} of Formula 3B, at least two of R^{C1}to R^{C5} of Formula 3C, at least two of R^{D1} to R^{D3} of Formula 3D, and at least two of R^{E1} to R^{E4} of Formula 3E are a group represented by Formula 1 or a group represented by Formula 2.

14. A method of manufacturing a semiconductor device, the method comprising:
forming a photoresist film by applying an extreme ultraviolet (EUV) photoresist composition on a film to be etched, the EUV photoresist composition including a polymer resin, a photoacid generator, a photo-decomposable quencher, and a photoreactive additive including at least two photo decomposable (DNQ) groups represented by Formula 1 or Formula 2 below;
forming bonds between the at least two DNQ groups and the polymer resin in the photoresist film;
exposing the photoresist film to EUV radiation; and
forming a photoresist pattern by removing a partial region of the photoresist film,

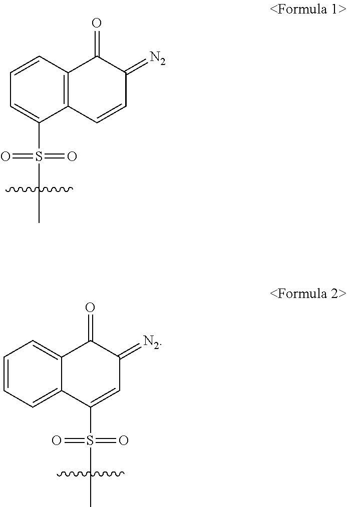

15. The method as claimed in claim 14, wherein:
the polymer resin includes at least one hydroxyl group, and
forming the bonds between the at least two DNQ groups and the polymer resin includes forming bonds between the at least two DNQ groups and the at least one hydroxyl group of the polymer resin.

16. The method as claimed in claim 14, wherein the polymer resin includes a resin in which a hydroxy styrene material monomer and a methacrylate monomer are polymerized.

17. The method as claimed in claim 14, wherein:
exposing the photoresist film to EUV radiation includes exposing a first region of the photoresist film to EUV radiation, and
forming the photoresist pattern includes forming the photoresist film consisting of an unexposed region by removing the exposed first region of the photoresist film.

18. The method as claimed in claim 14, wherein:
exposing the photoresist film to EUV radiation includes exposing a first region of the photoresist film to EUV radiation, and
the method further comprises breaking the bonds between the at least two DNQ groups and the polymer resin by exposing the at least two DNQ groups in the first region of the photoresist film to the EUV radiation.

19. The method as claimed in claim 18, wherein breaking the bonds between the at least two DNQ groups and the polymer resin includes breaking the bonds between the at least two DNQ groups and the polymer resin by exposing the bonds to secondary electrons emitted in response to the EUV radiation in the photoresist film.

20. The method as claimed in claim 14, wherein:
the photoreactive additive includes a compound represented by one of Formulae 3A to 3E below: 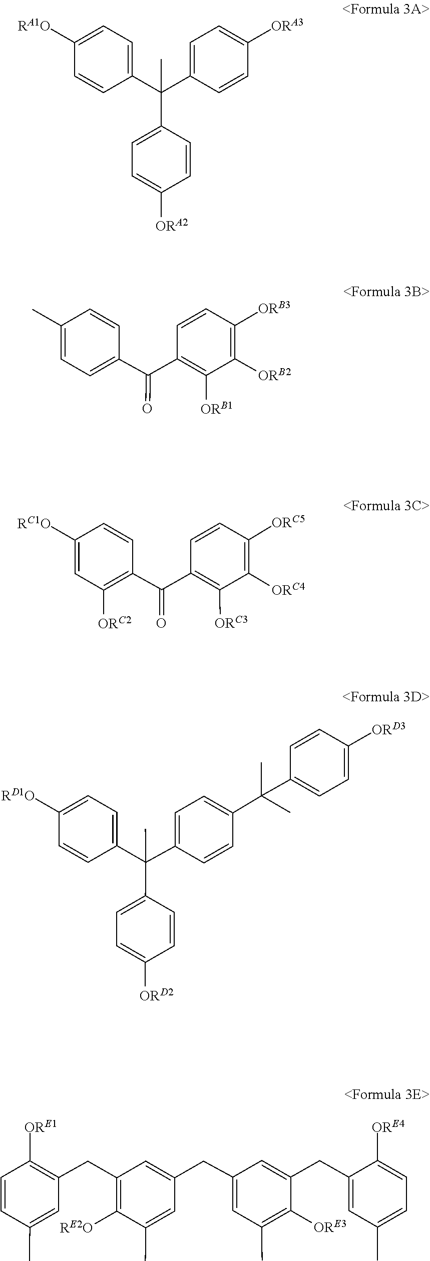
in Formulae 3A to 3E,
R^{A1} to R^{A3}, R^{B1} to R^{B3}, R^{C1}to R^{C5}, R^{D1} to R^{D3}, and R^{E1} to R^{E4} are each independently a group represented by Formula 1, a group represented by Formula 2, or a hydrogen atom, and
at least two of R^{A1} to R^{A3} of Formula 3A, at least two of R^{B1} to R^{B3} of Formula 3B, at least two of R^{C1}to R^{C5} of Formula 3C, at least two of R^{D1} to R^{D3} of Formula 3D, and at least two of R^{E1} to R^{E4} of Formula 3E are a group represented by Formula 1 or a group represented by Formula 2.
